(19) United States
(12) Patent Application Publication
(10) Pub. No.: US 2008/0093116 A1
(43) Pub. Date: Apr. 24, 2008

(54) SEMICONDUCTOR SUBSTRATE FOR TRANSMITTING DIFFERENTIAL PAIR

(75) Inventors: Pao-Nan Lee, Pingtung County (TW); Sung-Mao Wu, Kaohsiung (TW)

Correspondence Address: J C PATENTS, INC., 4 VENTURE, SUITE 250, IRVINE, CA, 92618, US

(73) Assignee: Advanced Semiconductor Engineering, Inc., Kaohsiung (TW)

(21) Appl. No.: 11/856,490

(22) Filed: Sep. 17, 2007

(30) Foreign Application Priority Data
Oct. 20, 2006 (TW) 95138865

(51) Int. Cl. H05K 1/11

(52) U.S. Cl. 174/261

(57) ABSTRACT

A semiconductor substrate for transmitting a differential pair is provided. The semiconductor substrate includes a substrate body and at least one via. The via has an opening on a surface layer of the substrate body and includes a first conductive element, a second conductive element and a ground element therein. The first conductive element, the second conductive element and the ground element are electrically isolated to one another. The ground element is electrically connected to a ground layer of the substrate body. The first conductive element and the second conductive element pass through the ground layer of the substrate body and are electrically isolated with the ground layer of the substrate body. The first conductive element is used for transmitting a positive differential signal and the second conductive element is used for transmitting a negative differential signal.

### CROSS-REFERENCE TO RELATED APPLICATION

This application claims the priority benefit of Taiwan application serial no. 95138865, filed on Oct. 20, 2006. All disclosure of the Taiwan application is incorporated herein by reference.

### BACKGROUND OF THE INVENTION

1. Field of the Invention

The present invention generally relates to a semiconductor substrate, and more particularly, to a semiconductor substrate for transmitting a differential pair in the same via.

2. Description of Related Art

A substrate is often designed to have a multi-layered structure in order to satisfy the need for high-density circuit. To connect these layers electrically with circuit on the substrate surface, a plurality of vias is disposed in the substrate. In addition, impedance control is an important topic in designing a differential pair. For a plane circuit, a good impedance design can be made because the upper layer or the lower layer has a complete reference plane. However, for vias (for example, blind via or through via), controlling the impedance is very difficult.

FIG. 1 is a diagram of a conventional semiconductor substrate for transmitting a differential pair. The semiconductor substrate 1 as shown in FIG. 1 includes a substrate body 11, a first via 12, a second via 13, a plurality of ground vias 14, a first circuit 15 and a second circuit 16. The substrate body 11 has a surface layer 111, a ground layer 112 and a plurality of dielectric layers 113. The ground layer 112 can be fully or partially distributed between two dielectric layers 113.

The first via 12, the second via 13 and the ground vias 14 are independent vias with openings on the surface layer 111 of the substrate body 11. The first via 12 has a first conductive element 121 therein. The second via 13 has a second conductive element 131 therein. The ground vias 14 surround the first via 12 and the second via 13, and each ground via 14 has a ground element 141 therein. The ground elements 141 are electrically connected to the ground layer 112 of the substrate body 11. The first conductive element 121 and the second conductive element 131 pass through the ground layer 112 of the substrate body 11 and are electrically isolated with the ground layer 112 of the substrate body 11.

The first circuit 15 is located on the surface layer 111 of the substrate body 11. The first circuit 15 is connected to the first conductive element 121 and is used for transmitting a positive differential signal. The second circuit 16 is located on the surface layer 111 of the substrate body 11. The second circuit 16 is connected to the second conductive element 131 and is used for transmitting a negative differential signal.

One defect of the conventional semiconductor substrate 1 is the impedance design of using the ground vias 14 to surround the first via 12 and the second via 13. This type of impedance design has the drawback of producing discontinuous points in the differential signal due to impedance mismatch, thereby lowering the electrical characteristic of the differential pair. In addition, a lot of area is occupied by the ground vias 14 surrounding the first via 12 and the second via 13.

### SUMMARY OF THE INVENTION

Accordingly, the present invention provides a semiconductor substrate for transmitting a differential pair. The semiconductor substrate includes a substrate body, at least one via, a first circuit and a second circuit. The substrate body has at least one surface layer and a ground layer. The via has an opening on the surface layer of the substrate body. The via includes a first conductive element, a second conductive element and a ground element therein. The first conductive element, the second conductive element and the ground element are electrically isolated to one another. The ground element is electrically connected to the ground layer of the substrate body. The first conductive element and the second conductive element pass through the ground layer of the substrate body and are electrically isolated with the ground layer of the substrate body. The first circuit is located on the surface layer of the substrate body. The first circuit is connected to the first conductive element and is used for transmitting a positive differential signal. The second circuit is located on the surface layer of the substrate body. The second circuit is connected to the second conductive element and is used for transmitting a negative differential signal.

Accordingly, three conductive elements are disposed inside the via. The first conductive element and the second conductive element can be respectively used for transmitting a positive and a negative differential signal. Furthermore, the ground element can be connected to a ground signal to serve as a reference plane for the impedance design. Thus, not only is the purpose of controlling the impedance inside the via achieved, but the effect is so positive that the electrical characteristics of the differential pair are also improved. In addition, one via instead of multiple vias is used to transmit a differential pair of signals in the present invention. Hence, the area occupied by the via is effectively reduced.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram of a conventional semiconductor substrate for transmitting a differential pair.

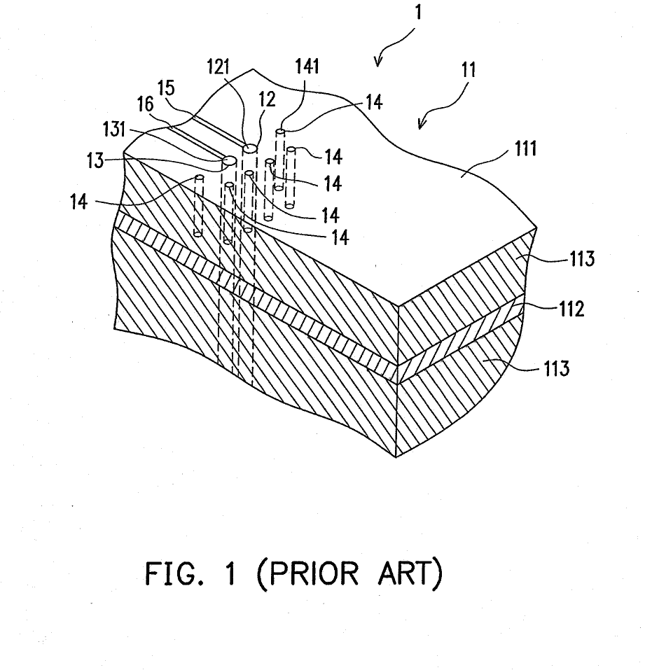

FIG. 2 is a diagram of a semiconductor substrate for transmitting a differential pair according to a first embodiment of the present invention.

FIG. 3 is a diagram of a semiconductor substrate for transmitting a differential pair according to a second embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

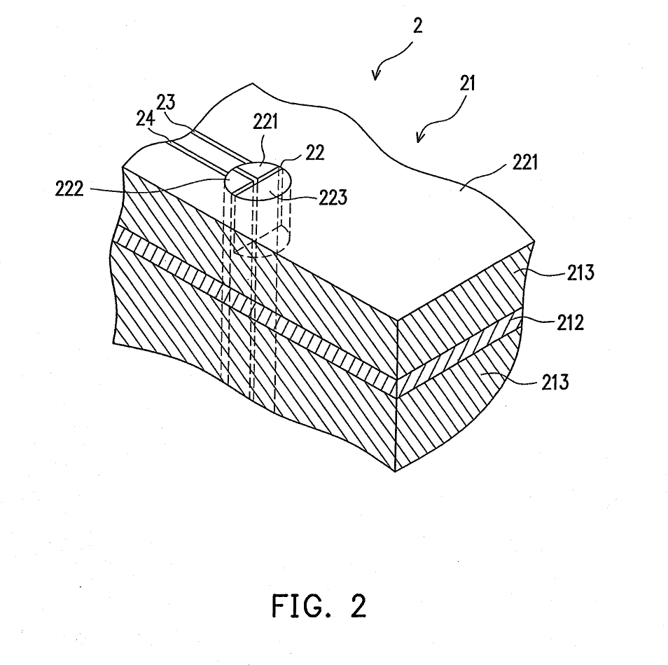

FIG. 2 is a diagram of a semiconductor substrate for transmitting a differential pair according to a first embodiment of the present invention. The semiconductor substrate 2 includes a substrate body 21, at least one via 22, a first circuit 23 and a second circuit 24. The substrate body 21 has a surface layer 211, a ground layer 212 and a plurality of dielectric layers 213. The ground layer 212 can be fully or partially distributed between two dielectric layers 213.

The via 22 has an opening on the surface layer 211 of the substrate body 21. The via 22 can be a blind via or a through via. The via 22 has a first conductive element 221, a second conductive element 222 and a ground element 223 therein. The first conductive element 221, the second conductive element 222 and the ground element 223 are separate and electrically isolated to one another. The ground element 223 is electrically connected to the ground layer 212 of the substrate body 21. The first conductive element 221 and the second conductive element 222 pass through the ground layer 212 of the substrate body 21 and are electrically isolated with the ground layer 212 of the substrate body 21.

In the present embodiment, the method of forming the first conductive element 221, the second conductive element 222 and the ground element 223 includes, for example, the following steps. First, the via 22 is filled with a conductive material such as a metal. Then, a laser cutting operation is performed to cut the block of conductive material in the via 22 into the form shown in FIG. 2. However, it should be noted that other method could be used to separate the first conductive element 221, the second conductive element 222 and the ground element 223. In the present embodiment, the first conductive element 221 and the second conductive element 222 are quadrants of a circle when viewed from the top view and the area of the quadrants are approximately equal. The ground element 223 is a semicircle with an area equal to the area of the first conductive element 221 and the second conductive element 222 combined. However, it should be noted that the first conductive element 221, the second conductive element 222 and the ground element 223 could be partitioned into other forms.

The first circuit 23 is located on the surface layer 211 of the substrate body 21. The first circuit 23 is connected to the first conductive element 221 and is used for transmitting a positive differential signal. The second circuit 24 is located on the surface layer 211 of the substrate body 21. The second circuit 24 is connected to the second conductive element 222 and is used for transmitting a negative differential signal.

One of the advantages of the present invention is the production of three conductive elements inside one via (that is, the via 22). Two of the conductive elements (the first conductive element 221 and the second conductive element 222) can be respectively used to transmit a positive and a negative differential signal. The other conductive element (the ground element 223) is connected to a ground signal to serve as a reference plane for the impedance design. Thus, not only is the purpose of controlling the impedance inside the via achieved, but the effect is so positive that the electrical characteristics of the differential pair are also improved. In addition, one via (the via 22) instead of multiple vias is used to transmit a differential pair of signals in the present invention. Hence, the area occupied by the via is effectively reduced.

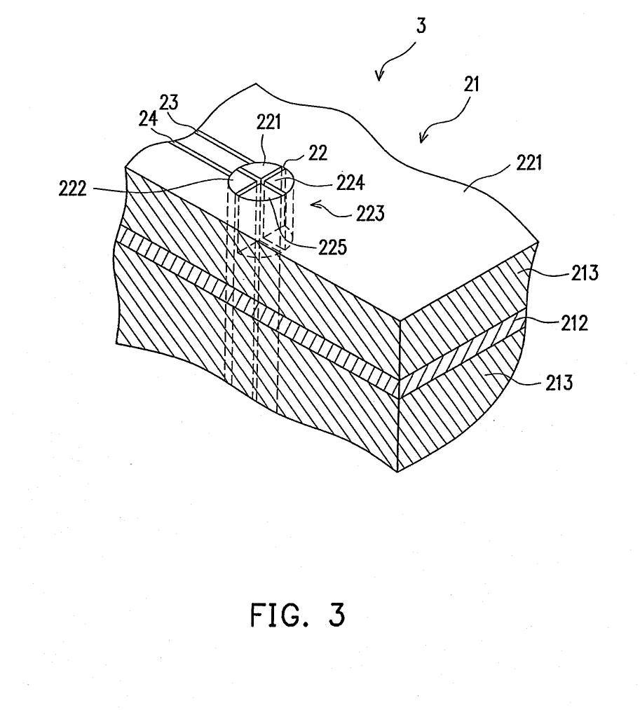

FIG. 3 is a diagram of a semiconductor substrate for transmitting a differential pair according to a second embodiment of the present invention. The semiconductor substrate 3 includes a substrate body 21, at least one via 22, a first circuit 23 and a second circuit 24. The substrate body 21 has a surface layer 211, a ground layer 212 and a plurality of dielectric layers 213. The ground layer 212 can be fully or partially distributed between two dielectric layers 213. The via 22 has a first conductive element 221, a second conductive element 222 and a ground element 223 therein. The ground element 223 includes a third conductive element 224 and a fourth conductive element 225. The first conductive element 221, the second conductive element 222, the third conductive element 224 and the fourth conductive element 225 are separate and electrically isolated to one another. The third conductive element 224 and the fourth conductive element 225 are electrically connected to the ground layer 212 of the substrate body 21. The first conductive element 221 and the second conductive element 222 pass through the ground layer 212 of the substrate body 21 and are electrically isolated with the ground layer 212 of the substrate body 21.

In the present embodiment, the method of forming the first conductive element 221, the second conductive element 222, the third conductive element 224 and the fourth conductive element 225 includes, for example, by laser cutting. However, it should be noted that other method could be used to separate the first conductive element 221, the second conductive element 222, the third conductive element 224 and the fourth conductive element 225. In the present embodiment, the first conductive element 221, the second conductive element 222, the third conductive element 224 and the fourth conductive element 225 are quadrants of a circle when viewed from the top view and the area of the quadrants are approximately equal. However, it should be noted that the first conductive element 221, the second conductive element 222, the third conductive element 224 and the fourth conductive element 225 could be partitioned into other forms.

The first circuit 23 is located on the surface layer 211 of the substrate body 21. The first circuit 23 is connected to the first conductive element 221 and is used for transmitting a positive differential signal. The second circuit 24 is located on the surface layer 211 of the substrate body 21. The second circuit 24 is connected to the second conductive element 222 and is used for transmitting a negative differential signal.

It should be noted that a better impedance control could be achieved because the semiconductor substrate 3 of the present embodiment has two ground elements (that is, the third conductive element 224 and the fourth conductive element 225).

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor substrate for transmitting a differential pair, comprising:
a substrate body, having at least one surface layer and one ground layer;
at least one via, having an opening on the surface layer of the substrate body and having a first conductive element, a second conductive element and at least one ground element therein, wherein the first conductive element, the second conductive element and the ground element are electrically isolated to one another, the ground element is electrically connected to the ground layer of the substrate body, and the first conductive element and the second conductive element pass through the ground layer of the substrate body and are electrically isolated with the ground layer of the substrate body;
a first circuit, located on the surface layer of the substrate body, wherein the first circuit is connected to the first conductive element and is used for transmitting a positive differential signal; and
a second circuit, located on the surface layer of the substrate body, wherein the second circuit is connected to the second conductive element and is used for transmitting a negative differential signal.

2. The semiconductor substrate according to claim 1, wherein the via is a blind via.

3. The semiconductor substrate according to claim 1, wherein the via is a through via.

4. The semiconductor substrate according to claim 1, wherein an area of the first conductive element from the top view is identical to an area of the second conductive element from the top view, and an area of the ground element from the top view is substantially equal to the sum of the area of the first conductive element and the second conductive element from the top view.

5. The semiconductor substrate according to claim 1, wherein the ground element comprises a third conductive element and a fourth conductive element, and the third conductive element and the fourth connective element are electrically isolated to each other but are electrically connected to the ground layer of the substrate body.

6. The semiconductor substrate according to claim 5, wherein, from the top view, an area of the first conductive element, an area of the second conductive element, an area of the third conductive element and an area of the fourth conductive element are identical.

7. The semiconductor substrate according to claim 1, wherein the substrate body further comprises a plurality of dielectric layers, and the ground layer is distributed between two dielectric layers.
